(19) United States
(12) Patent Application Publication
(10) Pub. No.: US 2007/0190712 A1
(43) Pub. Date: Aug. 16, 2007

(54) Semiconductor device having a trench gate and method of fabricating the same

(75) Inventors: Shian-Jyh Lin, Taipei County (TW); Chien-Li Cheng, Hsinchu City (TW); Chung-Yuan Lee, Taoyuan City (TW); Jeng-Ping Lin, Taoyuan County (TW); Pei-Ing Lee, Changhua County (TW)

Correspondence Address: QUINTERO LAW OFFICE, PC, 2210 MAIN STREET, SUITE 200, SANTA MONICA, CA, 90405, US

(73) Assignee: NANYA TECHNOLOGY CORPORATION, TAOYUAN (TW)

(21) Appl. No.: 11/521,639

(22) Filed: Sep. 14, 2006

(30) Foreign Application Priority Data
Feb. 10, 2006 (TW) TW95104600

(51) Int. Cl. H01L 21/8234

(52) U.S. Cl. 438/197

(57) ABSTRACT

A method of fabricating a semiconductor device having a trench gate is provided. First, a semiconductor substrate having a trench etch mask thereon is provided. The semiconductor substrate is etched to form a trench having a sidewall and a bottom using the trench etch mask as a shield. Impurities are doped into the semiconductor substrate through the trench to form a doped region. The semiconductor substrate underlying the trench is etched to form an extended portion. A gate insulating layer is formed on the trench and the extended portion. A trench gate is formed in the trench and the extended portion.

### BACKGROUND OF THE INVENTION

1. Field of the Invention

The invention relates to semiconductor fabrication, and more particularly relates to a metal oxide semiconductor transistor (MOS transistor) having a trench gate and a method of fabricating the same.

2. Description of the Related Art

Continuous development of semiconductor devices has resulted in devices, such as MOS transistors, capable of high performance, high integration and high operating speed. Continued integration demands that the size of MOS transistors on a semiconductor substrate must continuously be reduced. Higher integration of MOS transistors can be achieved, for example, by reducing gate length and/or source/drain region size. This method, however, may result in the short channel effect, significantly affecting the performance of semiconductor devices such as MOS transistors. U.S. Pat. No. 6,150,693 to Wollesen discloses a MOS transistor having a V-shaped trench and a gate oxide layer formed on the sidewall of the V-shaped trench. The gate fills the V-shaped trench. US patent publication No. 2005/0001252 A1 to Kim et al. discloses a MOS transistor semiconductor device having a trench gate to alleviate the short channel effect.

A method of fabricating a semiconductor device having a trench gate is provided. The method first selectively etches the semiconductor substrate to form a trench for a gate. A thick oxide of a predetermined thickness is deposited on the bottom of the trench. Dopants are driven into the semiconductor substrate through the trench to form a doped region serving as source/drain region followed by removal of the thick oxide. Thus, the thick oxide mainly determines the channel length of the semiconductor device, such as a metal-oxide semiconductor transistor.

Control of the thick oxide having a predetermined thickness, however, is difficult when filling the trench. This difficulty in control results in variation of the thickness of the thick oxide thus there is a problem of channel length variation as in the conventional methods.

### BRIEF SUMMARY OF THE INVENTION

Thus, an improved semiconductor device having a trench gate and a method of fabricating the capable of easy process control and of providing a semiconductor device with improved performance is desirable.

The invention provides a semiconductor device capable of improving the short channel effect.

The invention further provides a semiconductor device having a trench gate and a method of fabricating the same capable of easy control of the channel length and reduced channel length variation.

The invention further provides a semiconductor device having a trench gate capable of reducing the capacitance between the gate and drain (Cgd) and/or gate-induced drain leakage.

An exemplary embodiment of a method of fabricating a semiconductor device having a trench gate comprises the following steps. First, a semiconductor substrate having a trench etch mask thereon is provided. The semiconductor substrate is etched to form a trench having a sidewall and a bottom using the trench etch mask as a shield. Impurities are doped into the semiconductor substrate through the trench to form a doped region. The semiconductor substrate underlying the trench is etched to form an extended portion. A gate insulating layer is formed on the trench and the extended portion. A trench gate is formed in the trench and the extended portion.

Another exemplary embodiment of a semiconductor device having a trench gate comprises a semiconductor substrate, a trench disposed in the semiconductor substrate wherein the trench has an extended portion and a gate insulating layer formed on a sidewall of the trench and a surface of the extended portion. The semiconductor device further comprises a doped region formed in the semiconductor substrate adjacent to the sidewall of the trench, a recessed channel in the semiconductor substrate underlying the extended portion of the trench and a gate formed in the trench including the extended portion.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIGS. 1 to 8 show cross sections of an exemplary process flow of manufacturing a semiconductor device having a trench gate; and

FIGS. 9 to 16 are cross sections of another exemplary process flow of manufacturing a semiconductor device having a trench gate.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

In this specification, expressions such as “overlying the substrate”, “above the layer”, or “on the film” simply denote a relative positional relationship with respect to the surface of a base layer, regardless of the existence of intermediate layers. Accordingly, these expressions may indicate not only the direct contact of layers, but also, a non-contact state of one or more laminated layers.

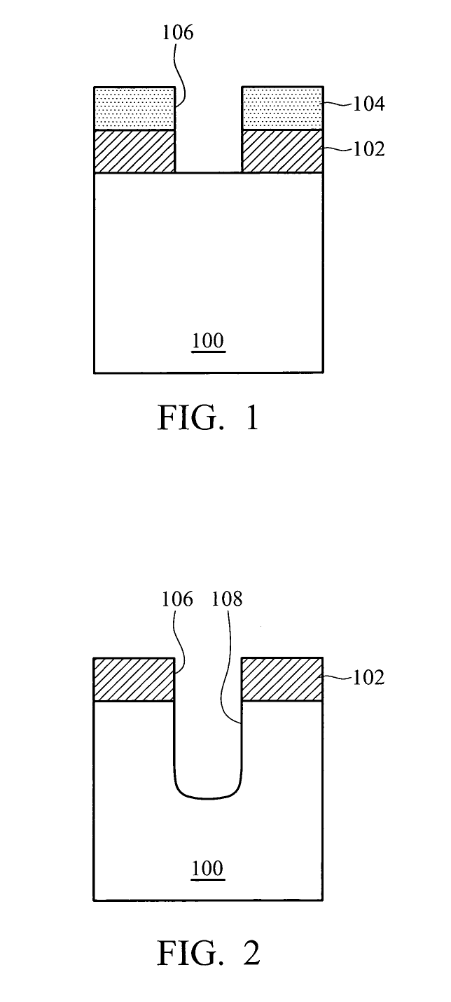

FIGS. 1 to 8 are cross sections of an exemplary process flow of manufacturing a semiconductor device having a trench gate.

As shown in FIG. 1, a semiconductor substrate 100 is provided. The semiconductor substrate 100 may comprise silicon, gallium arsenide, gallium nitride, strained silicon, silicon germanium, silicon carbide, carbide, diamond, an epitaxy layer and/or other materials, and preferably is a silicon substrate. A hard mask layer comprising silicon oxide, silicon nitride or silicon oxynitride is formed on the semiconductor substrate 100. A photoresist pattern 104 having an opening 106 is formed on the hard mask layer by photolithography. The opening 106 corresponds to a trench for provided for forming a gate. The hard mask layer is etched using the photoresist pattern 104 as a mask through the opening 106 to form a trench etch mask 102.

As shown in FIG. 2, the photoresist pattern 104 is stripped. Using the trench etch mask 102 as a shield, the semiconductor substrate 100 is etched to form a trench 108 having a depth of about 1000 Å to about 3000 Å, preferably about 1500 Å. The semiconductor substrate 100 is preferably etched by reactive ion etching (RIE) using an etching gas comprising Cl₂, HBr, O₂, CF₄ or SF₆.

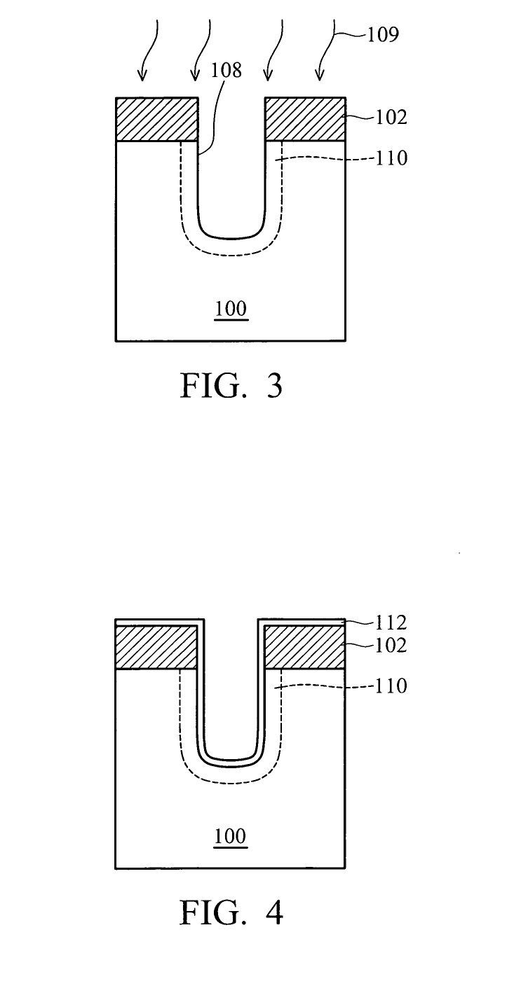

As shown in FIG. 3, gas phase doping (GPD) is performed. That is, gaseous dopants 109 are doped into the semiconductor substrate 100 through the sidewall and the bottom of the trench 108 so as to form a doped region 110 serving as a self-aligned source/drain. The gaseous dopants 109 may contain n-type or p-type impurities (dopants) such as ions of As, P, B, or Sb.

Then, as shown in FIG. 4, a dielectric liner 112, composed of silicon oxide, silicon nitride or silicon oxy-nitride, is conformally formed on the sidewall and the bottom of the trench 108. The dielectric liner 112 is formed for example by plasma enhanced chemical vapor deposition (PECVD), low pressure chemical vapor deposition (LPCVD) or atomic layer chemical vapor deposition (ALCVD). The thickness of the dielectric liner 112 is preferably about 10 Å to 300 Å.

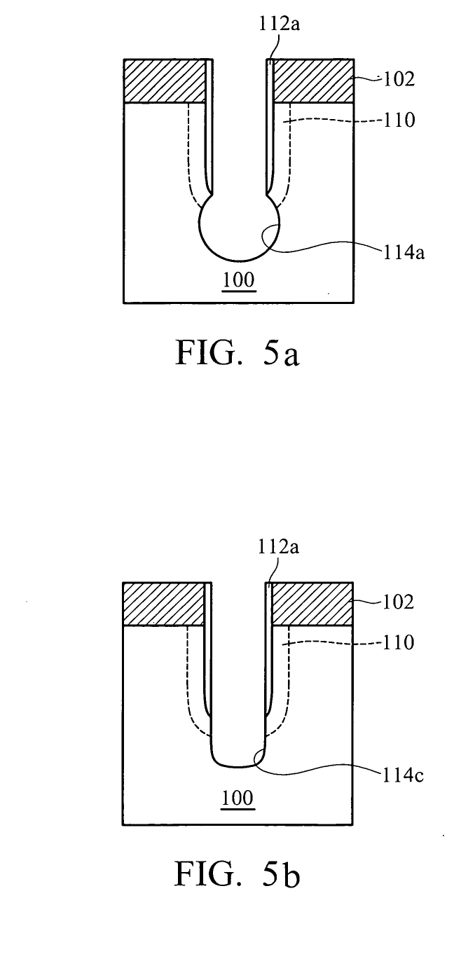

Referring now to FIG. 5a, an etching back process is performed to remove the dielectric liner 112 on the upper surface of the trench etch mask 102 and on the bottom of the trench 108, thus, a dielectric liner spacer 112a remains along the sidewall of the trench 108. The semiconductor substrate 100 and the doped region 110 underlying the trench 108 are then etched to form a bowl-shaped extended portion 114a using the dielectric liner spacer 112a as a mask. The semiconductor substrate 100 and the doped region 110 are preferably etched by reactive ion etching (RIE) using an etching gas comprising Cl₂, HBr, O₂, CF₄ or SF₆. A wet etching may be used to replace RIE.

Alternatively, a cylinder-shaped extended portion 114c is formed as shown in FIG. 5b by dry etching or wet etching.

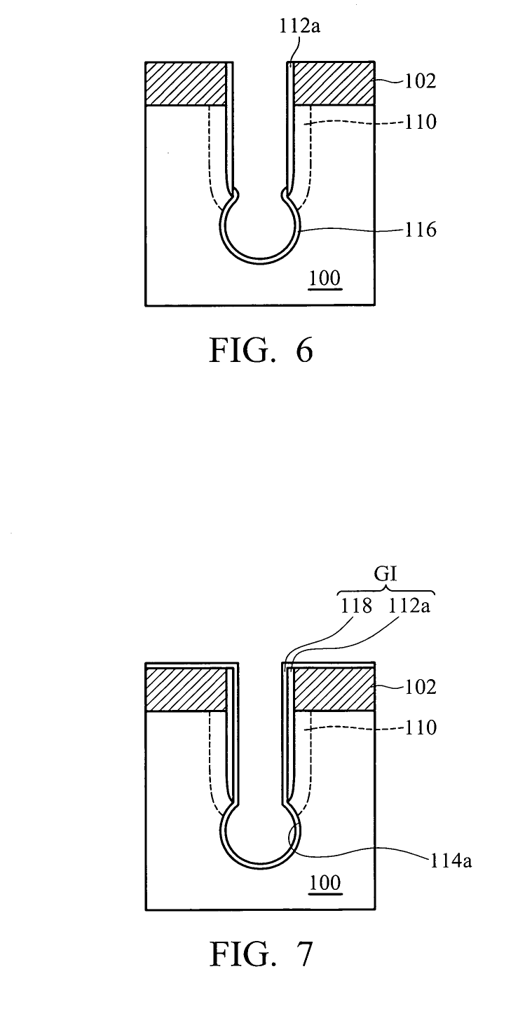

FIG. 6 and FIG. 7 show cross sections of the semiconductor device fabricated according to the semiconductor device of FIG. 5a. A sacrificial oxide layer 116 is then formed by rapid thermal process (RTP) at 800° C. to 900° C. in an ambient comprising oxygen or water on the surface of the bowl-shaped extended portion 114a. The sacrificial oxide layer 116 has a thickness of about 100 Å to 300 Å. Next, the sacrificial oxide layer 116 is removed by an etchant comprising hydrofluoric acid to repair the surface of the semiconductor substrate 100 exposed in the bowl-shaped extended portion 114a. That is, the rough surface of the semiconductor substrate 100 resulting from etching of the extended portion 114a can be smoothed. An insulating layer 118 serving as a gate insulating layer is conformally deposited on the dielectric liner spacer 112a and the bowl-shaped extended portion 114a by chemical vapor deposition. The insulating layer 118 may comprise silicon oxide, silicon nitride, silicon oxynitride, tantalum oxide (Ta₂O₅) or other high-k dielectric layer (k>7). The thickness of the gate insulating layer GI at the sidewall portion of the trench 108 is equal to the total thickness of the insulating layer 118 and the dielectric liner spacer 112a while the thickness of the gate insulating layer GI at the bowl-shaped extended portion 114a is equal to the thickness of the insulating layer 118. Thus, capacitance between the gate and drain (Cgd) can be reduced and/or gate-induced drain leakage can be reduced as the dimensions of the semiconductor device are scaled down.

Alternatively, the dielectric liner spacer 112a may be removed before formation of the insulating layer 118. In other embodiments, the insulating layer 118 comprising oxide may be formed on the trench 108 and the bowl-shaped extended portion 114a by thermal oxidation to serve as the gate insulating layer.

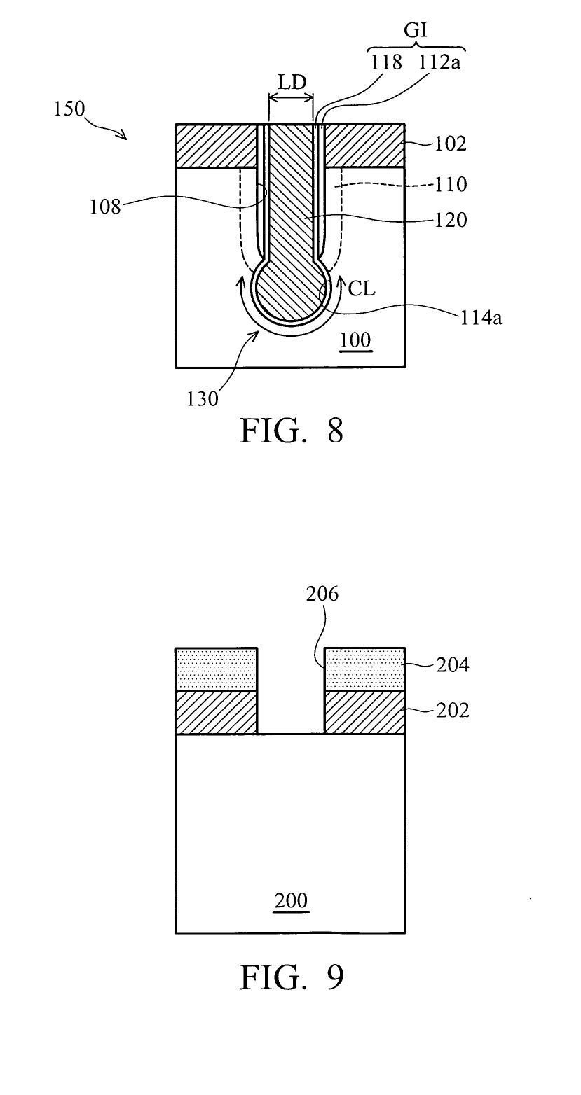

As shown in FIG. 8, a conductive layer such as a doped polysilicon layer is then blanket deposited by plasma enhanced chemical vapor deposition (PECVD), low pressure chemical vapor deposition (LPCVD), or high density plasma chemical vapor deposition (HDPCVD) filling into the trench 108 and the bowl-shaped extended portion 114a. Alternatively, a conductive layer comprising aluminum, copper, tungsten, or an alloy thereof can be used to replace the doped polysilicon layer. Then, the conductive layer is then planarized by chemical mechanical polish (CMP) to form a trench gate 120.

Alternatively, the trench gate 120 may be formed by selectively etching the conductive layer using a photoresist pattern formed in advance by photolithography as an etch mask. Next, the photoresist pattern is stripped.

An ion implantation is optionally performed in the surface of the semiconductor substrate 100 adjacent to the doped region 110 so as to form a source/drain extended portion (not shown) after removing the trench etch mask 102.

Referring now to FIG. 8, a semiconductor device 150 fabricated by an exemplary process flow is shown. The semiconductor device 150, metal-oxide transistor (MOS), includes a semiconductor substrate 100 and a trench 108 disposed in the semiconductor substrate 100, wherein the trench 108 has an extended portion 114a. The semiconductor device 150 further comprises a gate insulating layer GI formed on a sidewall of the trench 108 and a surface of the extended portion 114a. The semiconductor device 150 comprises a doped region 110 formed in the semiconductor substrate 100 adjacent to the sidewall of the trench 108. The semiconductor device 150 further comprises a recessed channel 130 in the semiconductor substrate 100 underlying the extended portion 114a of the trench 108 and a trench gate 120 formed in the trench 108 including the extended portion 114a. The recessed channel 130 preferably has a channel length CL greater than 1.2 times of a lateral dimension LD of the trench 108. More preferably, the recessed channel 130 has a channel length CL of about 1.5 to 3 times of the lateral dimension LD of the trench 108. The channel length CL is measured from the center of the trench 108. Accordingly, poor device performance caused by the short channel effect in small size semiconductor devices can be prevented.

FIGS. 9 to 16 are cross sections of another exemplary process flow of manufacturing a semiconductor device having a trench gate.

As shown in FIG. 9, a semiconductor substrate 200 is provided. The semiconductor substrate 200 may comprise silicon, gallium arsenide, gallium nitride, strained silicon, silicon germanium, silicon carbide, carbide, diamond, an epitaxy layer and/or other materials, and preferably is a silicon substrate. A hard mask layer comprising silicon oxide, silicon nitride or silicon oxynitride is formed on the semiconductor substrate 200. A photoresist pattern 204 having an opening 206 is formed on the hard mask layer by photolithography. The opening 206 corresponds to a trench for provided for forming a gate. The hard mask layer is etched using the photoresist pattern 204 as a mask through the opening 206 to form a trench etch mask 202.

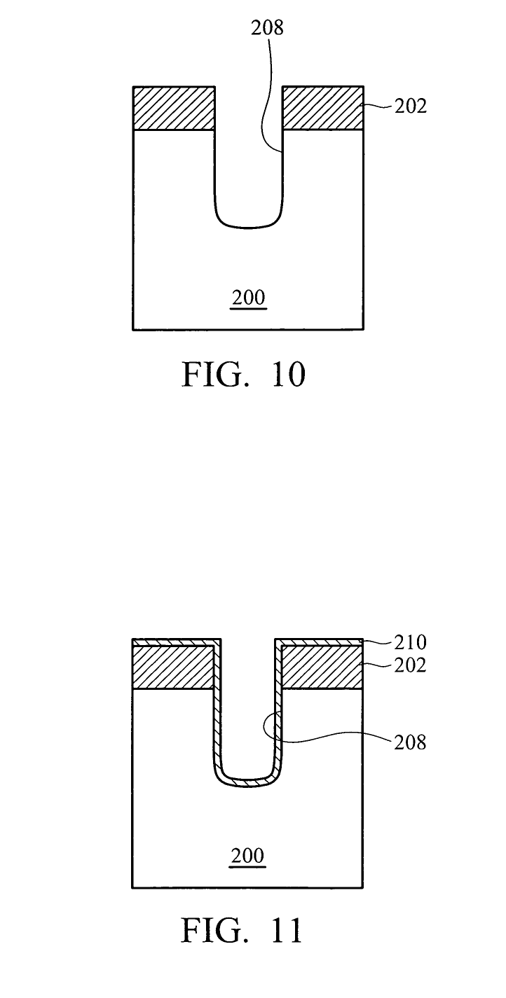

As shown in FIG. 10, the photoresist pattern 204 is stripped. Using the trench etch mask 202 as a shield, the semiconductor substrate 200 is etched to form a trench 208 having a depth of about 1000 Å to about 3000 Å, preferably about 1500 Å. The semiconductor substrate 200 is preferably etched by reactive ion etching (RIE) using an etching gas comprising Cl₂, HBr, O₂, CF₄ or SF₆.

As shown in FIG. 11, a doped insulating layer 210 having a thickness of about 10 Å to 200 Å is conformally formed on the sidewall of and the bottom of the trench 208. The doped insulating layer 210 may contain n-type or p-type impurities (dopants). The doped insulating layer 210 is for example phosphosilicate glass (PSG), arsenic silicate glass (ASG) or borosilicate glass (BSG). Moreover, the doped insulating layer 210 may be formed by plasma enhanced chemical vapor deposition (PECVD), low pressure chemical vapor deposition (LPCVD) or atomic layer chemical vapor deposition (ALCVD).

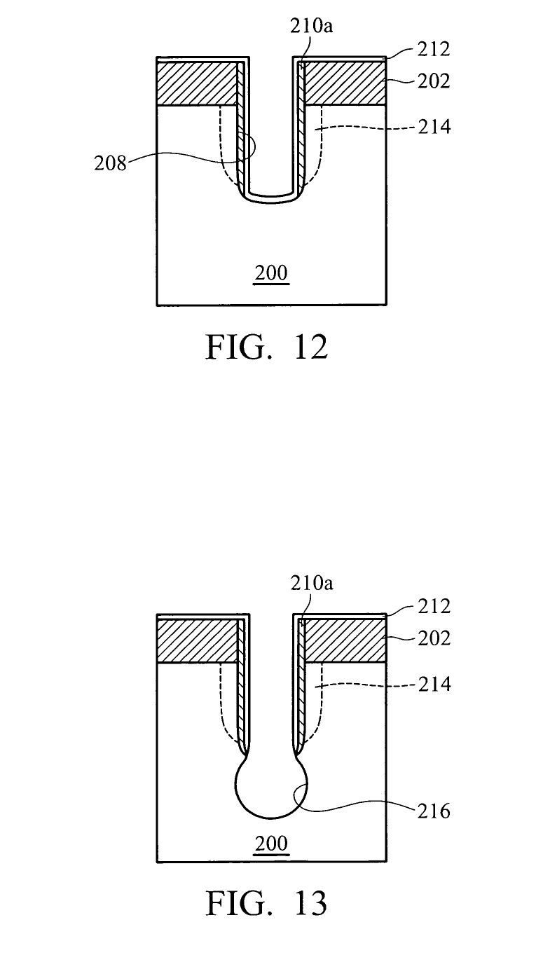

As shown in FIG. 12, an etching process is performed to remove the doped insulating layer 210 from the bottom of the trench 208, thus, a doped insulating spacer 210a remains along the trench 208. Then, a dielectric liner 212, comprising silicon oxide, silicon nitride or silicon oxy-nitride, is conformally formed on the sidewall and the bottom of the trench 208. The dielectric liner 212 is formed for example by plasma enhanced chemical vapor deposition (PECVD), low pressure chemical vapor deposition (LPCVD) or atomic layer chemical vapor deposition (ALCVD). The thickness of the dielectric liner 212 is preferably about 10 Å to 300 Å. Next, the impurities of the doped insulating spacer 210a are out-diffused and driven into the semiconductor substrate 200 adjacent to the doped insulating spacer 210a so as to form a doped region 214 by rapid thermal process (RTP) at 800° C. to 1000° C. The doped region 214 has a depth of about 100 Å to 1000 Å, preferably 300 Å. The dielectric liner 212 aids in driving the impurities of the doped insulating spacer 210a into the semiconductor substrate 200 adjacent to the sidewall of the trench 208 without diffusing toward the interior of the trench 208. Thus, the dielectric liner 212 may improve diffusion efficiency during formation of the doped region 214.

Referring now to FIG. 13, the dielectric liner 212 on at least the bottom of the trench 208 is etched to expose the semiconductor substrate 200. The dielectric liner 212 on the trench etch mask 202 may be or may not be removed at the same time. The semiconductor substrate 200 is etched from the bottom of the trench 208 using the trench etch mask 202 and the dielectric liner 212 as the etch mask to form a bowl-shaped extended portion 216. The semiconductor substrate 200 is preferably etched by reactive ion etching (RIE) using an etching gas comprising Cl₂, HBr, O₂, CF₄ or SF₆. A wet etching may be used to replace RIE.

Note that the doped region 214 does not extend to the bottom of the trench 208. The doped region 110 underlying the bottom of the trench 108 should be completely removed as shown in FIG. 5a during formation of the extended portion 114a. There is no need to completely remove the doped region under the bottom of the trench as compared with the previously described process mentioned. The channel length of semiconductor device increases and the process of forming the extended portion 216 can be easily controlled.

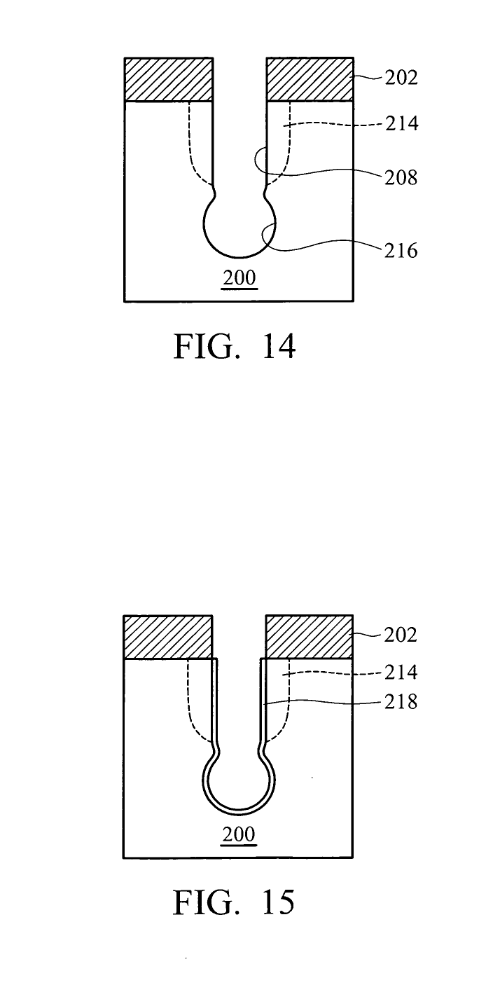

Referring to FIG. 13 and FIG. 14, a sacrificial oxide layer is optionally formed on the surface of the bowl-shaped extended portion 216 by rapid thermal process (RTP) at 800° C. to 900° C. in an ambient comprising oxygen or water. The sacrificial oxide layer may have a thickness of about 100 Å to 300 Å. Next, the sacrificial oxide layer is removed by an etchant comprising hydrofluoric acid to repair the surface of the semiconductor substrate 200 exposed in the bowl-shaped extended portion 216. That is, the rough surface of the semiconductor substrate 200 caused by the etching process of the extended portion 216 can be smoothed. Next, the dielectric liner 212 and doped insulating spacer 210a are completely removed by etching using hydrofluoric acid or phosphoric acid as shown in FIG. 14.

As shown in FIG. 15, a gate insulating layer 218 having a thickness of about 10 Å to 300 Å is conformally deposited on the trench 208 and the bowl-shaped extended portion 218 by chemical vapor deposition. The gate insulating layer 218 may comprise silicon oxide, silicon nitride, silicon oxynitride, tantalum oxide (Ta₂O₅) or other high-k dielectric layer (k>7). Alternatively, the gate insulating layer 218 is formed on the trench 208 and the bowl-shaped extended portion 218 by thermal oxidation.

Note that the gate insulating layer 218 formed by thermal oxidation has a relatively thicker portion adjacent to the doped region 214 because the oxidation rate of the doped region 214 is greater than that of the semiconductor substrate 200. Thus, capacitance between the gate and drain (Cgd) can be reduced and/or gate-induced drain leakage can be reduced as the dimension of semiconductor device is shrunk.

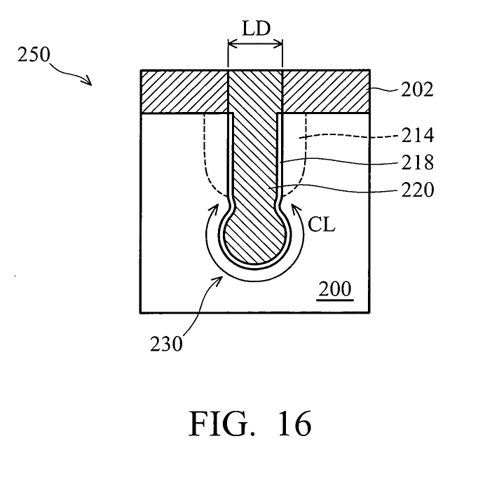

As shown in FIG. 16, a conductive layer such as a doped polysilicon layer is then blanket deposited by plasma enhanced chemical vapor deposition (PECVD), low pressure chemical vapor deposition (LPCVD), or high density plasma chemical vapor deposition (HDPCVD) filling into the trench 208 and the bowl-shaped extended portion 216. Alternatively, a conductive layer comprising aluminum, copper, tungsten, or an alloy thereof can be used to replace the doped polysilicon layer. The conductive layer is then planarized by chemical mechanical polish (CMP) to form a trench gate 220.

Alternatively, the trench gate 220 may be formed by selectively etching the conductive layer using a photoresist pattern formed in advance by photolithography as an etch mask. Next, the photoresist pattern is stripped.

An ion implantation is optionally performed on the surface of the semiconductor substrate 200 adjacent to the doped region 214 so as to form a source/drain extended portion (not shown) after removing he trench etch mask 102.

Referring now to FIG. 16, a semiconductor device 250 fabricated by the exemplary process flow mentioned above is shown. The semiconductor device 250, metal-oxide transistor (MOS), includes a semiconductor substrate 200 and a trench 208 disposed in the semiconductor substrate 200, wherein the trench 208 has an extended portion 216. Moreover, the semiconductor device 250 further comprises a gate insulating layer 218 formed on a sidewall of the trench 208 and a surface of the extended portion 216. The semiconductor device 250 comprises a doped region 214 formed in the semiconductor substrate 200 adjacent to the sidewall of the trench 208. The semiconductor device 250 further comprises a recessed channel 230 in the semiconductor substrate 200 underlying the extended portion 216 of the trench 208 and a trench gate 220 formed in the trench 208. The recessed channel 230 preferably has a channel length CL greater than 1.2 times of a lateral dimension LD of the trench 208. More preferably, the recessed channel 230 has a channel length CL of about 1.5 to 3 times of the lateral dimension LD of the trench 208. The channel length CL is measured from the center of the trench 208. Accordingly, poor device performance caused by the short channel effect of small size semiconductor devices can be prevented.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method of fabricating a semiconductor device having a trench gate, comprising:
providing a semiconductor substrate having a trench etch mask thereon;
etching the semiconductor substrate to form a trench having a sidewall and a bottom using the trench etch mask as a shield;
doping impurities into the semiconductor substrate through the trench to form a doped region;
etching the semiconductor substrate underlying the trench to form an extended portion;
forming a gate insulating layer on the trench and the extended portion; and
forming a trench gate in the trench and the extended portion.

2. The method of fabricating a semiconductor device having a trench gate as claimed in claim 1, wherein forming the trench etch mask further comprises:
forming a silicon nitride layer on the semiconductor substrate;
forming a photoresist pattern having an opening on the silicon nitride layer by photolithography;
etching the silicon nitride layer through the opening using the photoresist pattern as a mask to form the trench etch mask; and
removing the photoresist pattern.

3. The method of fabricating a semiconductor device having a trench gate as claimed in claim 1, wherein the doped region is formed by doping impurities using gas phase doping (GPD) or liquid phase doping (LPD).

4. The method of fabricating a semiconductor device having a trench gate as claimed in claim 1, wherein the impurities comprise As, P, B, or Sb.

5. The method of fabricating a semiconductor device having a trench gate as claimed in claim 1, further comprising forming a dielectric liner on the sidewall of the trench before forming the extended portion.

6. The method of fabricating a semiconductor device having a trench gate as claimed in claim 5, further comprising removing the dielectric liner before forming the gate insulating layer.

7. The method of fabricating a semiconductor device having a trench gate as claimed in claim 1, wherein the gate insulating layer is formed by thermal oxidation or chemical vapor deposition.

8. The method of fabricating a semiconductor device having a trench gate as claimed in claim 1, wherein the extended portion is cylinder-shaped or bowl-shaped.

9. The method of fabricating a semiconductor device having a trench gate as claimed in claim 1, further comprising:
forming a sacrificial oxide layer on a surface of the extended portion by thermal oxidation before forming the extended portion; and
removing the sacrificial oxide layer.

10. The method of fabricating a semiconductor device having a trench gate as claimed in claim 1, wherein forming the doped region further comprising:
conformally forming a doped insulating layer on the sidewall and the bottom of the trench removing the doped insulating layer at the bottom of the trench to leave a doped insulating spacer;
forming a dielectric liner on the doped insulating spacer; and
driving dopants of the doped insulating spacer into the semiconductor substrate adjacent to the doped insulating spacer by thermal oxidation.

11. The method of fabricating a semiconductor device having a trench gate as claimed in claim 10, further comprising removing the dielectric liner and the doped insulating spacer before forming the gate insulating layer.

12. The method of fabricating a semiconductor device having a trench gate as claimed in claim 10, wherein the doped insulating layer comprises phosphosilicate glass (PSG), arsenic silicate glass (ASG) or borosilicate glass (BSG).

13. The method of fabricating a semiconductor device having a trench gate as claimed in claim 11, wherein the doped insulating spacer is removed by an etching gas comprising hydrofluoric gas or an etchant comprising hydrofluoric acid.

14. The method of fabricating a semiconductor device having a trench gate as claimed in claim 10, wherein the thermal oxidation is rapid thermal oxidation and is performed at a temperature about 300° C. to 500° C.

15. The method of fabricating a semiconductor device having a trench gate as claimed in claim 1, further comprising a doping step for a channel.

16. A semiconductor device having a trench gate, comprising:
a semiconductor substrate;
a trench disposed in the semiconductor substrate wherein the trench has an extended portion;
a gate insulating layer formed on a sidewall of the trench and a surface of the extended portion;
a doped region formed in the semiconductor substrate adjacent to the sidewall of the trench;
a recessed channel in the semiconductor substrate underlying the extended portion of the trench; and
a gate formed in the trench including the extended portion.

17. The semiconductor device having a trench gate as claimed in claim 16, the recessed channel has a length greater than 1.2 times the lateral dimension of the trench.

18. The semiconductor device having a trench gate as claimed in claim 16, the recessed channel has a length of about 1.5 to 3 times the lateral dimension of the trench.
